(19) United States
(12) Patent Application Publication
(10) Pub. No.: US 2025/0113543 A1
(43) Pub. Date: Apr. 3, 2025

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Kentaro MIURA, Tokyo (JP); Akihiro HANADA, Tokyo (JP); Masahiro WATABE, Tokyo (JP)

(73) Assignee: Japan Display Inc., Tokyo (JP)

(21) Appl. No.: 18/895,479

(22) Filed: Sep. 25, 2024

(30) Foreign Application Priority Data
Sep. 29, 2023 (JP) 2023-170308

(51) Int. Cl. H01L 29/786; H01L 29/423

(52) U.S. Cl. CPC H10D 30/6755; H10D 30/673; H10D 30/6757

(57) ABSTRACT

A semiconductor device according to an embodiment of the present invention includes an oxide semiconductor layer having a polycrystalline structure and including an impurity region containing an impurity element, a gate electrode over the oxide semiconductor layer, an insulating layer between the oxide semiconductor layer and the gate electrode, a first contact hole penetrating the insulating layer and exposing the impurity region, a second contact hole penetrating at least the insulating layer and having a greater depth than the first contact hole, and a connection wiring electrically connecting the impurity region to a layer which is exposed in the second contact hole through the first contact hole and the second contact hole. The connection wiring includes a first conductive layer and a second conductive layer on the first conductive layer. A portion of the first conductive layer that is exposed from the second conductive layer contains the impurity element.

### CROSS-REFERENCE TO RELATED APPLICATION

This application claims the benefit of priority to Japanese Patent Application No. 2023-170308, filed on Sep. 29, 2023, the entire contents of which are incorporated herein by reference.

### FIELD

An embodiment of the present invention relates to a semiconductor device using an oxide semiconductor having a polycrystalline structure.

### BACKGROUND

In recent years, instead of a silicon semiconductor film using amorphous silicon, low-temperature polysilicon, and single-crystal silicon, a semiconductor device including an oxide semiconductor film has been developed (for example, see Japanese laid-open patent publication No. 2021-141338, Japanese laid-open patent publication No. 2014-099601, Japanese laid-open patent publication No. 2021-153196, Japanese laid-open patent publication No. 2018-006730, Japanese laid-open patent publication No. 2016-184771, and Japanese laid-open patent publication No. 2021-108405). The semiconductor device including an oxide semiconductor film has a simple structure and can be manufactured by a low-temperature process, similar to a semiconductor device including an amorphous silicon film. Further, the semiconductor device including an oxide semiconductor film is known to have a higher field effect mobility than the semiconductor device including an amorphous silicon film.

### SUMMARY

A semiconductor device according to an embodiment of the present invention includes an oxide semiconductor layer having a polycrystalline structure and including an impurity region containing an impurity element, a gate electrode over the oxide semiconductor layer, an insulating layer between the oxide semiconductor layer and the gate electrode, a first contact hole penetrating the insulating layer and exposing the impurity region, a second contact hole penetrating at least the insulating layer and having a greater depth than the first contact hole, and a connection wiring electrically connecting the impurity region to a layer which is exposed in the second contact hole through the first contact hole and the second contact hole. The connection wiring includes a first conductive layer and a second conductive layer on the first conductive layer. A portion of the first conductive layer that is exposed from the second conductive layer contains the impurity element.

### BRIEF DESCRIPTION OF DRAWINGS

FIG. 1 is a schematic cross-sectional view showing a configuration of a semiconductor device according to an embodiment of the present invention.

FIG. 2 is a schematic enlarged cross-sectional view showing a configuration of a semiconductor device according to an embodiment of the present invention.

FIG. 3 is a schematic cross-sectional view showing a method for manufacturing a semiconductor device according to an embodiment of the present invention.

FIG. 4 is a schematic cross-sectional view showing a method for manufacturing a semiconductor device according to an embodiment of the present invention.

FIG. 5 is a schematic cross-sectional view showing a method for manufacturing a semiconductor device according to an embodiment of the present invention.

FIG. 6 is a schematic cross-sectional view showing a method for manufacturing a semiconductor device according to an embodiment of the present invention.

FIG. 7 shows a result of a simulation showing a concentration profile of boron implanted into an oxide semiconductor layer.

FIG. 8 is a schematic cross-sectional view showing a configuration of a semiconductor device according to a modification of an embodiment of the present invention.

FIG. 9 is a schematic cross-sectional view showing a configuration of a semiconductor device according to a modification of an embodiment of the present invention.

FIG. 10 is a schematic cross-sectional view showing a configuration of a semiconductor device according to a modification of an embodiment of the present invention.

FIG. 11 is a schematic cross-sectional view showing a configuration of a semiconductor device according to a modification of an embodiment of the present invention.

FIG. 12 is a schematic cross-sectional view showing a configuration of a semiconductor device according to an embodiment of the present invention.

### DESCRIPTION OF EMBODIMENTS

A semiconductor device is required to have not only a high field effect mobility but also high reliability. An embodiment of the present invention can provide a semiconductor device having high reliability.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a semiconductor device and a pixel electrode do not overlap in a plan view when expressed as “a pixel electrode over a semiconductor device.” On the other hand, the expression “a pixel electrode vertically over a semiconductor device” means a positional relationship in which the semiconductor device and the pixel electrode overlap in a plan view. In addition, a plan view refers to viewing from a direction perpendicular to a surface of the substrate.

In the present specification and the like, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In the present specification and the like, a “semiconductor device” refers to any device that can function by utilizing semiconductor properties. A transistor and a semiconductor circuit are included in one form of a semiconductor device. For example, the semiconductor device in the following embodiments may be, an integrated circuit (IC) such as a display device or a micro-processing unit (MPU), or a transistor used in a memory circuit.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction.

In the present specification and the like, the terms “film” and “layer” can be optionally interchanged with one another.

In addition, the following embodiments can be combined with each other as long as there is no technical contradiction.

### First Embodiment

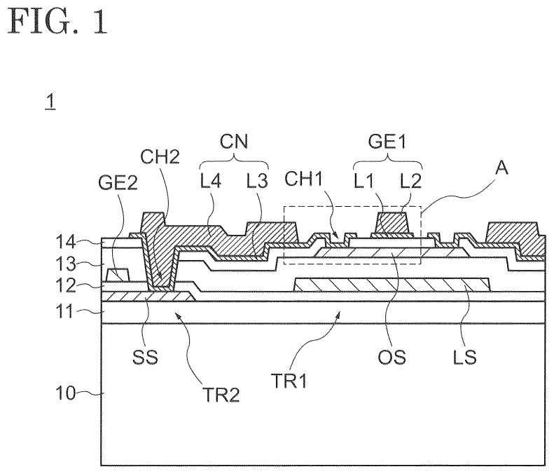

A semiconductor device 1 according to an embodiment of the present invention is described with reference to FIGS. 1 to 10.

### [1. Configuration of Semiconductor Device 1]

FIG. 1 is a schematic cross-sectional view showing a configuration of the semiconductor device 1 according to an embodiment of the present invention.

As shown in FIG. 1, the semiconductor device 1 includes a first transistor TR1 and a second transistor TR2 over a substrate 10. The semiconductor device 1 also includes insulating layers 11 to 14 that are provided commonly in the first transistor TR1 and the second transistor TR2.

The first transistor TR1 includes an insulating layer 11, an insulating layer 12, a light shielding layer LS, an insulating layer 13, an oxide semiconductor layer OS, an insulating layer 14, and a gate electrode GE1. The insulating layer 11 is provided on a substrate 10. The insulating layer 12 is provided on the insulating layer 11. The light shielding layer LS is provided on the insulating layer 12. The insulating layer 13 is provided on the insulating layer 12 so as to cover an upper surface and an edge surface of the light shielding layer LS. The oxide semiconductor layer OS is provided on the insulating layer 13. The insulating layer 14 is provided on the insulating layer 13 so as to cover an upper surface and an edge surface of the oxide semiconductor layer OS. The gate electrode GE1 is provided on the insulating layer 14 so as to overlap the oxide semiconductor layer OS. In the first transistor TR1, the insulating layer 11 and the insulating layer 12 function as base insulating layers, the insulating layer 13 functions as an interlayer insulating layer, and the insulating layer 14 functions as a gate insulating layer. The gate electrode GE1 is an electrode electrically connected to a gate line. In addition, a detailed configuration of the oxide semiconductor layer OS is described later.

The second transistor TR2 includes the insulating layer 11, a silicon semiconductor layer SS, the insulating layer 12, a gate electrode GE2, the insulating layer 13, and the insulating layer 14. The insulating layer 11 is provided on the substrate 10. The silicon semiconductor layer SS is provided on the insulating layer 11. The insulating layer 12 is provided on the insulating layer 11 so as to cover an upper surface and an edge surface of the silicon semiconductor layer SS. The gate electrode GE2 is provided on the insulating layer 12 so as to overlap the silicon semiconductor layer SS. The insulating layer 13 is provided on the insulating layer 12 so as to cover an upper surface and an edge surface of the gate electrode GE2. The insulating layer 14 is provided on the insulating layer 13. In the second transistor TR2, the insulating layer 11 functions as a base insulating layer, the insulating layer 12 functions as a gate insulating layer, and the insulating layer 13 and the insulating layer 14 function as interlayer insulating layers. The gate electrode GE2 is an electrode electrically connected to a gate line. Although the silicon semiconductor layer SS may be, for example, a polycrystalline silicon semiconductor, a material of the silicon semiconductor layer SS is not limited thereto. Other silicon-based semiconductors may also be used for the silicon semiconductor layer SS.

The first transistor TR1 and the second transistor TR2 are electrically connected via a connection wiring CN. Specifically, the connection wiring CN directly electrically connects the oxide semiconductor layer OS of the first transistor TR1 and the second transistor TR2. The connection wiring CN functions as one of the source electrode and the drain electrode of the first transistor TR1. The connection wiring CN also functions as one of the source electrode and the drain electrode of the second transistor TR2. In addition, the other of the source electrode and the drain electrode of the second transistor TR2 is omitted from the illustration in FIG. 1.

The substrate 10 can support each layer constituting the semiconductor device 1. For example, a rigid substrate having light-transmitting properties, such as a glass substrate, a quartz substrate, or a sapphire substrate, can be used as the substrate 10. Further, a rigid substrate having no light-transmitting properties, such as a silicon substrate, can also be used as the substrate 10. A flexible substrate having light-transmitting properties, such as a polyimide resin substrate, an acrylic resin substrate, a siloxane resin substrate, or a fluorine resin substrate, can also be used as the substrate 10. Impurities may be introduced into the flexible substrate in order to improve the heat resistance of the substrate 10.

The light shielding layer LS can reflect or absorb light incident on the side of the substrate 10. In other words, the light shielding layer LS can shield light incident on the oxide semiconductor layer OS. The light shielding layer LS is formed in the same layer as the gate electrode GE2. That is, the light shielding layer is formed of the same material as the gate electrode GE2. For example, a metal such as aluminum (Al), copper (Cu), titanium (Ti), molybdenum (Mo), or tungsten (W), or an alloy or compound thereof can be used for the light shielding layer LS. The light shielding layer LS may have a single layer structure or a stacked structure.

For example, an oxide such as silicon oxide (SiOₓ), silicon oxynitride (SiOₓN_{y}), aluminum oxide (AlOₓ), or aluminum oxynitride (AlOₓN_{y}), or a nitride such as silicon nitride (SiNₓ), silicon nitride oxide (SiNₓO_{y}), aluminum nitride (AlNₓ), or aluminum nitride oxide (AlNₓO_{y}) can be used for each of the insulating layers 11 to 14. Each of the insulating layers 11 to 14 may have a single layer structure or a stacked structure.

Here, silicon oxynitride (SiOₓN_{y}) and aluminum oxynitride (AlOₓN_{y}) are oxides that contain a smaller proportion (x>y) of nitrogen (N) than oxygen (O). Further, silicon nitride oxide (SiNₓO_{y}) and aluminum nitride oxide (AlNₓO_{y}) are nitrides that contain a smaller proportion (x>y) of oxygen than nitrogen. In addition, silicon oxide (SiOₓ) and silicon oxynitride (SiOₓN_{y}) may be simply referred to as “silicon oxide” and silicon nitride (SiNₓ) and silicon nitride oxide (SiNₓO_{y}) may be simply referred to as “silicon nitride,” for convenience of explanation. Similarly, aluminum oxide (AlOₓ) and aluminum oxynitride (AlOₓN_{y}) may be simply referred to as “aluminum oxide” and aluminum nitride (AlNₓ) and aluminum nitride oxide (AlNₓO_{y}) may be simply referred to as “aluminum nitride.”

It is preferable that the insulating layers 13 and 14 in contact with the oxide semiconductor layer OS contain an oxide. When the oxide semiconductor layer OS is in contact with an oxide, oxygen can be supplied from the oxide to the oxide semiconductor layer OS by a heat treatment. For example, the insulating layer 13 may have a stacked structure including silicon nitride and silicon oxide on the silicon nitride. Further, the insulating layer 14 may have a single layer structure of silicon oxide.

The gate electrode GE1 is formed in the same layer as the connection wiring CN. That is, the gate electrode GE1 is formed of the same material as the connection wiring CN. Each of the gate electrode GE1 and the connection wiring CN has a stacked structure. Specifically, the gate electrode GE1 has a stacked structure including a first conductive layer L1 and a second conductive layer L2 on the first conductive layer L1. Further, the connection wiring CN has a stacked structure including a third conductive layer L3 and a fourth conductive layer L4 on the third conductive layer L3. The first conductive layer L1 is formed in the same layer as the third conductive layer L3, and the second conductive layer L2 is formed in the same layer as the fourth conductive layer L4.

In a channel length direction of the first transistor TR1 (a direction from the source electrode to the drain electrode of the first transistor TR1 or a direction from the drain electrode to the source electrode of the first transistor TR1), a width of the first conductive layer L1 is larger than a width of the second conductive layer L2. Therefore, in a plan view, the first conductive layer L1 includes a portion exposed from the second conductive layer L2. Further, a thickness t1 of the first conductive layer L1 is smaller than a thickness t2 of the second conductive layer L2 (t1<t2). The thickness t2 of the second conductive layer L2 is greater than or equal to three times the thickness t1 of the first conductive layer L1. For example, the thickness t1 is about 30 nm, and the thickness t2 is about 100 nm.

The first conductive layer L1 is formed of a material different from the second conductive layer L2. When selecting the materials of the first conductive layer L1 and the second conductive layer L2, it is preferable that the density of the material forming the first conductive layer L1 is smaller than the density of the material forming the second conductive layer L2. The same material as the gate electrode GE2 can be used for the first conductive layer L1 and the second conductive layer L2. For example, the first conductive layer L1 contains at least one of titanium (Ti) and aluminum (Al), and the second conductive layer L2 contains at least one of molybdenum (Mo) and tungsten (W). However, since the first conductive layer L1 is in contact with the oxide semiconductor layer OS, it is preferable that the first conductive layer L1 contains a material that is not easily oxidized. For example, it is preferable that the first conductive layer L1 has a single layer structure of titanium or a stacked structure including titanium and aluminum on titanium.

The first transistor TR1 is provided with a first contact hole CH1 that penetrates the insulating layer 14 and exposes a part of the oxide semiconductor layer OS. The second transistor TR2 is provided with a second contact hole CH2 that penetrates the insulating layers 12 to 14 and exposes a part of the silicon semiconductor layer SS. A depth of the second contact hole CH2 is greater than a depth of the first contact hole CH1. The connection wiring CN electrically connects the oxide semiconductor layer OS and the silicon semiconductor layer SS through the first contact hole CH1 and the second contact hole CH2.

As described above, the connection wiring CN includes the third conductive layer L3 formed in the same layer as the first conductive layer L1 and the fourth conductive layer LS4 formed in the same layer as the second conductive layer L2. Therefore, a thickness t3 of the third conductive layer L3 is smaller than a thickness t4 of the fourth conductive layer L4 (t3<t4). The thickness t4 of the fourth conductive layer L4 is greater than or equal to three times the thickness t3 of the third conductive layer L3. For example, the thickness t3 is about 30 nm, and the thickness t4 is about 100 nm.

The third conductive layer L3 extends from the first contact hole CH1 to the second contact hole CH2 so as to cover the first contact hole CH1 and the second contact hole CH2. The third conductive layer L3 is in contact with the oxide semiconductor layer OS through the first contact hole CH1 and is in contact with the silicon semiconductor layer SS through the second contact hole CH2.

Although the fourth conductive layer L4 overlaps the second contact hole CH2, the fourth conductive layer L4 does not overlap the first contact hole CH1. That is, in the connection wiring CN, a part of the third conductive layer L3 is exposed from the fourth conductive layer L4. The part of the third conductive layer exposed from the fourth conductive layer L4 is in contact with the oxide semiconductor layer OS through the first contact hole CH1.

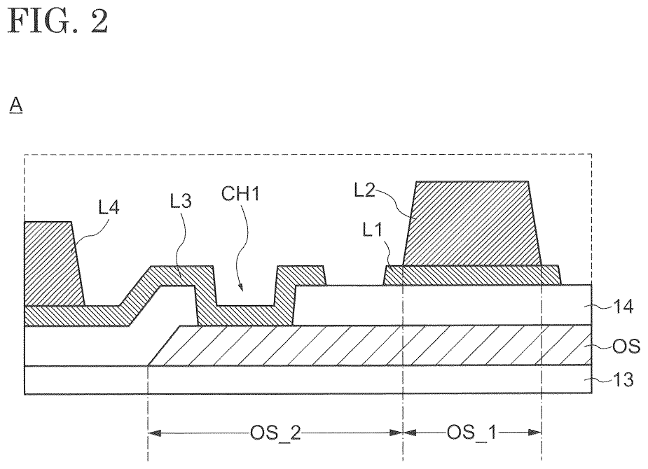

Here, the electrical connection between the connection wiring CN and the oxide semiconductor layer is described with reference to FIG. 2.

FIG. 2 is a schematic enlarged cross-sectional view showing a configuration of the semiconductor device 1 according to an embodiment of the present invention. Specifically, FIG. 2 is a cross-sectional view showing an enlarged region A in FIG. 1.

The oxide semiconductor layer OS includes a channel region OS_1 and an impurity region OS_2 adjacent to the channel region. The channel region OS_1 has properties of a semiconductor. Therefore, when a voltage is applied to the gate electrode GE1, a channel that functions as a current path is formed in the channel region OS_1. The impurity region OS_2 contains an impurity element and has properties of a conductor. Therefore, a carrier concentration of the impurity region OS_2 is higher than a carrier concentration of the channel region OS_1. In other words, the channel region OS_1 has a higher electric resistivity (or a lower electric conductivity) than the impurity region OS_2. For example, the sheet resistance of the impurity region OS_2 is less than or equal to 1000 Ω/sq., preferably less than or equal to 500 Ω/sq., and more preferably less than or equal to 250 Ω/sq. In addition, the impurity region OS_2 may be called a source region or a drain region.

Although the impurity element contained in the impurity region OS_2 is, for example, boron (B) or phosphorus (P), the impurity element is not limited thereto. Although the details are described later, the impurity region OS_2 containing the impurity element can be formed by implanting the impurity element into the oxide semiconductor layer OS. The impurity region OS_2 of the oxide semiconductor layer OS can contain a larger amount of the impurity element. This means that a larger number of oxygen deficiencies in the impurity region OS_2 is generated and the impurity region OS_2 has a sufficiently high carrier concentration. Therefore, the resistance of the impurity region OS_2 is sufficiently low.

The boundary between the channel region OS_1 and the impurity region OS_2 substantially coincides with an edge portion of the second conductive layer L2. That is, an edge portion of the impurity region OS_2 overlaps a portion of the first conductive layer L1 that is exposed from the second conductive layer L2.

The third conductive layer L3 is in contact with the impurity region OS_2 through the first contact hole CH1. Since the resistance of the impurity region OS_2 is sufficiently low, the electrical connection between the third conductive layer L3 and the impurity region OS_2 is an ohmic contact.

### [2. Configuration of Oxide Semiconductor Layer OS]

### [2-1. Composition of Oxide Semiconductor Layer OS]

An oxide semiconductor containing two or more metal elements including indium (In) is used for the oxide semiconductor layer OS. Gallium (Ga), zinc (Zn), aluminum (Al), hafnium (Hf), yttrium (Y), zirconium (Zr), and lanthanoids are used as a metal element other than indium.

The oxide semiconductor layer OS has light-transmitting properties and a polycrystalline structure including a plurality of crystal grains. It is preferable to use an oxide semiconductor in which the ratio of indium to all metal elements is greater than or equal to 50% in an atomic ratio so that the oxide semiconductor layer OS has a polycrystalline structure. When the ratio of the indium is increased, the oxide semiconductor layer OS is easily crystallized. Further, it is preferable that gallium is included in the metal elements other than indium. Gallium belongs to the same Group 13 elements as indium. Therefore, the crystallinity of the oxide semiconductor layer OS is hardly inhibited by gallium.

Although the oxide semiconductor layer OS includes the channel region OS_1 and the impurity region OS_2, not only the channel region OS_1 but also the impurity region OS_2 may have a polycrystalline structure. In this case, the crystal structure of the channel region OS_1 is the same as the crystal structure of the impurity region OS_2.

Although the details are described later, the oxide semiconductor layer OS has properties different from a conventional oxide semiconductor having a polycrystalline structure. Therefore, in order to distinguish the oxide semiconductor included in the oxide semiconductor layer OS from the conventional oxide semiconductor having a polycrystalline structure, the oxide semiconductor contained in the oxide semiconductor layer OS is referred to as Poly-crystalline Oxide Semiconductor (Poly-OS) in the following description.

The Poly-OS contained in the oxide semiconductor layer OS can be formed by a sputtering method and a heat treatment. Here, a method for forming the oxide semiconductor layer OS is described.

First, an oxide semiconductor film is deposited using a sputtering method. The oxide semiconductor film to be deposited has an amorphous structure. Here, the amorphous structure refers to a structure in which a long-range ordered structure does not exist and a periodic crystal lattice arrangement is not observed. For example, when the oxide semiconductor film having an amorphous structure is observed by X-ray diffraction (XRD), specific peaks due to a crystal structure are not obtained in the diffraction pattern. In addition, the oxide semiconductor film having an amorphous structure may have a short-range ordered structure in a microscopic region. However, such an oxide semiconductor film does not exhibit characteristics of Poly-OS and can be classified as the oxide semiconductor film having an amorphous structure.

The oxide semiconductor film having an amorphous structure is deposited at a low temperature. For example, the temperature of the substrate on which the oxide semiconductor film is deposited is lower than or equal to 150° C., preferably lower than or equal to 100° C., and more preferably lower than or equal to 50° C. When the temperature of the substrate is high, it is likely to generate microcrystals in the oxide semiconductor film to be deposited. Further, the oxygen partial pressure in the chamber during film formation is greater than or equal to 1% and less than or equal to 10%, preferably greater than or equal to 1% and less than or equal to 5%, and more preferably greater than or equal to 2% and less than or equal to 4%. When the oxygen partial pressure is large, microcrystals are generated in the oxide semiconductor film due to excess oxygen contained in the oxide semiconductor. On the other hand, under the condition where the oxygen partial pressure is less than 1%, the oxygen composition in the oxide semiconductor film becomes non-uniform, and an oxide semiconductor film including many microcrystals or an oxide semiconductor film that does not crystallize even when a heat treatment is performed is deposited.

Next, a heat treatment is performed on the oxide semiconductor film formed using a sputtering method. Although the heat treatment is performed in air, the atmosphere is not limited thereto. The temperature of the heat treatment is higher than or equal to 300° C. and lower than or equal to 500° C., and preferably higher than or equal to 350° C. and lower than or equal to 450° C. The time of the heat treatment is greater than or equal to 15 minutes and less than or equal to 120 minutes, and preferably greater than or equal to 30 minutes and less than or equal to 60 minutes. When the heat treatment is performed, the oxide semiconductor film having an amorphous structure is crystallized, and the oxide semiconductor layer OS containing Poly-OS is formed.

The composition of the oxide semiconductor layer OS is approximately the same as that of the sputtering target. Therefore, the composition of the metal elements of the oxide semiconductor layer OS can be specified based on the composition of the metal elements of the sputtering target. The composition of the oxide semiconductor layer OS may be specified using the XRD method. Specifically, the composition of the metal elements of the oxide semiconductor layer OS can be specified based on the crystal structure and lattice constant of the oxide semiconductor layer OS obtained by the XRD method. Further, the composition of the metal elements of the oxide semiconductor layer OS can also be specified using X-ray fluorescence analysis or Electron Probe Micro Analyzer (EPMA) analysis. In addition, oxygen contained in the oxide semiconductor layer OS is not limited thereto because oxygen changes depending on the process conditions for a sputtering method and the like.

### [2-2. Characteristics of Oxide Semiconductor Layer OS]

Next, characteristics of the oxide semiconductor layer OS containing Poly-OS are described.

The oxide semiconductor layer OS has excellent etching resistance. Specifically, the etching rate of the oxide semiconductor layer OS is very small when the oxide semiconductor layer OS is etched using an etching solution for wet etching. This means that the oxide semiconductor layer OS is hardly etched by the etching solution. The etching rate when the oxide semiconductor layer OS is etched using an etching solution containing phosphoric acid as a main component at 40° C. (hereinafter, referred to as a “mixed acid etching solution”) is less than 3 nm/min, less than 2 nm/min, or less than 1 nm/min. The ratio of phosphoric acid in the mixed acid etching solution is greater than or equal to 50%, greater than or equal to 60%, or greater than or equal to 70%. The mixed acid etching solution may contain acetic acid and nitric acid in addition to phosphoric acid. In addition, when an oxide semiconductor film not containing Poly-OS, for example, the oxide semiconductor film having an amorphous structure before the heat treatment, is etched using the mixed acid etching solution at 40° C., the etching rate of the oxide semiconductor film is greater than or equal to 100 nm/min. The etching rate when the oxide semiconductor layer OS is etched using 0.5% of a hydrofluoric acid solution at room temperature is less than 5 nm/min, less than 4 nm/min, or less than 3 nm/min. When the oxide semiconductor film not containing Poly-OS is etched using 0.5% of the hydrofluoric acid solution at room temperature, the etching rate of the oxide semiconductor film is greater than or equal to 15 nm/min. Here, “40° C.” refers to 40+5° C. and may be the temperature of the etching solution or the set temperature of the etching solution. Further, “room temperature” refers to 25±5° C.

Examples of the oxide semiconductor layer OS are shown in Table 1. Table 1 shows the etching rates of each of the prepared samples with respect to a mixed acid etching solution (“Mixed Acid AT-2F” manufactured by Rasa Kogyo Co., Ltd., in which the ratio of phosphoric acid in the mixed acid etching solution is 65%) and 0.5% of a hydrofluoric acid solution. When each sample was etched, the temperature of the mixed acid etching solution was 40° C., and the temperature of 0.5% of the hydrofluoric acid solution was room temperature. In Table 1, Sample 1 is the oxide semiconductor layer OS containing Poly-OS, Sample 2 is an oxide semiconductor film having an amorphous structure before the heat treatment, and Sample 3 is an oxide semiconductor film containing indium gallium zinc oxide (IGZO) in which the ratio of indium is less than 50%.

TABLE 1

| | Mixed acid etching | 0.5% of hydrofluoric |
|---|---|---|
| | solution | acid solution |
| Sample 1 | <0.1 nm/min | <2 nm/min |
| Sample 2 | 111 nm/min | >18 nm/min |
| Sample 3 | 162 nm/min | — |

As shown in Table 1, Sample 1 (oxide semiconductor layer OS containing Poly-OS) is hardly etched using the mixed acid etching solution, and is etched at only 2 nm/min at most even when 0.5% of the hydrofluoric acid solution is used. In etching using the mixed acid etching solution, the etching rate of Sample 1 is less than or equal to 1/100 of the etching rate of Sample 2 (oxide semiconductor film having an amorphous structure before the heat treatment). In etching using 0.5% of the hydrofluoric acid solution, the etching rate of Sample 1 is less than or equal to approximately 1/10 the etching rate of Sample 2. Further, when etching using the mixed acid etching solution, the etching rate of Sample 1 is less than or equal to 1/100 of the etching rate of Sample 3 (oxide semiconductor film containing IGZO in which the ratio of indium is less than 50%). That is, Sample 1 has significantly better etching resistance than Samples 2 and 3.

Such an excellent etching resistance of the oxide semiconductor layer OS containing the Poly-OS is a characteristic that cannot be obtained with the conventional oxide semiconductor having a polycrystalline structure, which is manufactured by a process lower than or equal to 500° C. Although the detailed mechanism of the excellent etching resistance of the oxide semiconductor layer OS containing the Poly-OS is unclear, it is considered that the Poly-OS has a polycrystalline structure different from that of a conventional oxide semiconductor.

As described above, the oxide semiconductor layer OS containing the Poly-OS has a very low etching rate with respect to an etching solution. Therefore, it is very difficult to pattern the oxide semiconductor layer OS. Thus, when the oxide semiconductor layer OS is formed in an island shape, the oxide semiconductor film having an amorphous structure before the heat treatment is patterned in an island shape, and then the oxide semiconductor film is crystallized by performing the heat treatment. In this way, the island-shaped oxide semiconductor layer OS containing the Poly-OS can be formed.

### [3. Manufacturing Method of Semiconductor Device 1]

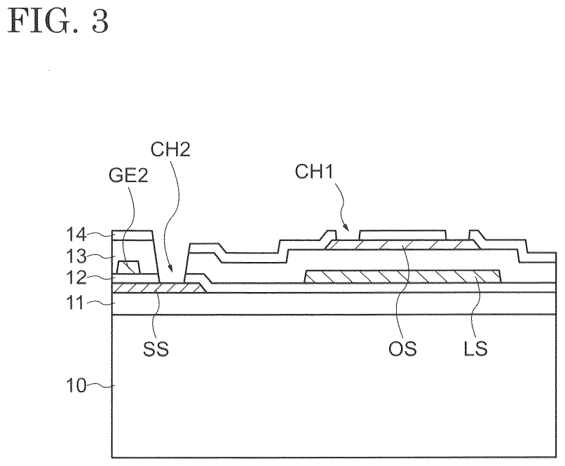

A method for manufacturing the semiconductor device 1 is described with reference to FIGS. 3 to 6.

FIGS. 3 to 6 are schematic cross-sectional views showing a method for manufacturing the semiconductor device 1 according to an embodiment of the present invention.

First, as shown in FIG. 3, the insulating layer 11, the silicon semiconductor layer SS, the insulating layer 12, the gate electrode GE2 and the light shielding layer LS, the insulating layer 13, the oxide semiconductor layer OS, and the insulating layer 14 are sequentially formed on the substrate 10.

In forming the silicon semiconductor layer SS, an impurity element is implanted into the silicon semiconductor layer SS using the gate electrode GE1 as a mask. The implanted impurity element is phosphorus (P) in the case of an n-channel type, and boron (B) in the case of a p-channel type. In forming the oxide semiconductor layer OS, a heat treatment (hereinafter, referred to as “OS annealing”) is performed after patterning an oxide semiconductor film deposited using a sputtering method. When OS annealing is performed, the oxide semiconductor layer OS containing Poly-OS is formed.

Further, the first contact hole CH1 penetrating the insulating layer 14 and the second contact hole CH2 penetrating the insulating layers 12 to 14 are formed after forming the insulating layer 14. A part of the oxide semiconductor layer OS is exposed in the first contact hole CH1, and a part of the silicon semiconductor layer SS is exposed in the second contact hole CH2.

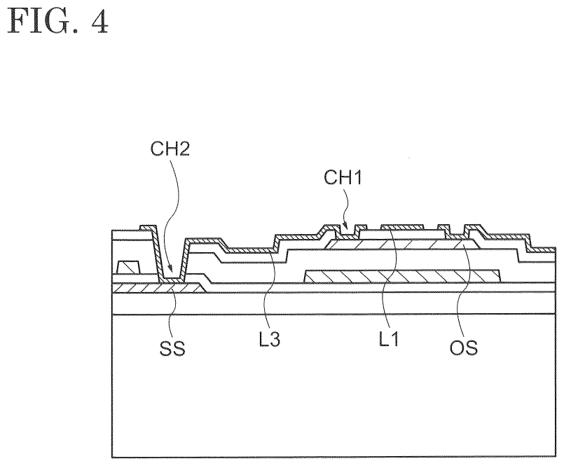

Next, as shown in FIG. 4, the first conductive layer L1 of the gate electrode GE2 and the third conductive layer L3 of the connection wiring CN are formed when a metal film is deposited on the insulating layer 14 and then the metal film is patterned. The third conductive layer L3 is in contact with the oxide semiconductor layer OS through the first contact hole CH1 and in contact with the silicon semiconductor layer SS through the second contact hole CH2. The first conductive layer L1 overlaps the oxide semiconductor layer OS and is separated from the third conductive layer L3.

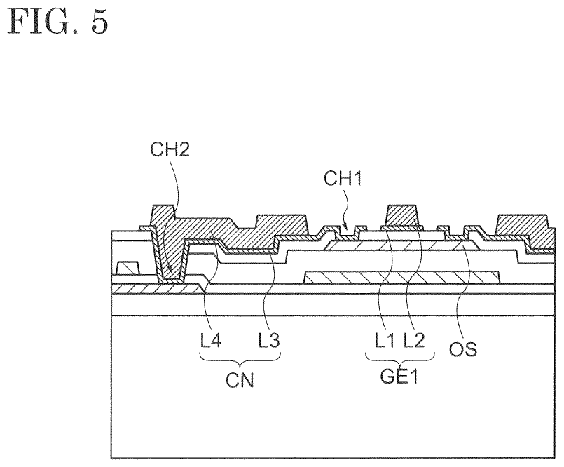

Next, as shown in FIG. 5, the second conductive layer L2 of the gate electrode GE1 and the fourth conductive layer L4 of the connection wiring CN are formed when a metal film is deposited on the first conductive layer L1 and the third conductive layer L3 and then the metal film is patterned. Although the fourth conductive layer L4 overlaps the second contact hole CH2, the fourth conductive layer L4 does not overlap the first contact hole CH1. The second conductive layer L2 overlaps the oxide semiconductor layer OS and is separated from the fourth conductive layer L4.

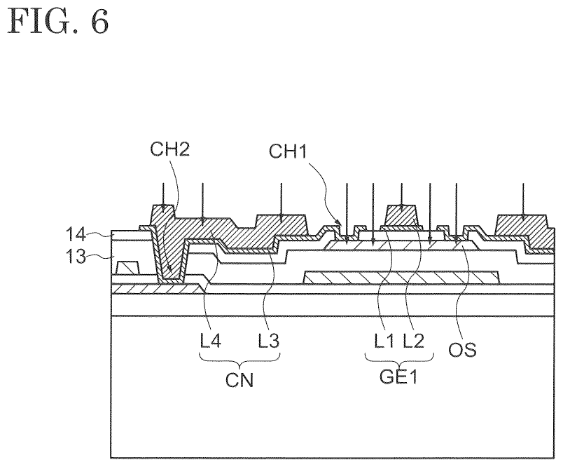

Next, as shown in FIG. 6, the impurity element is implanted into the oxide semiconductor layer OS using the gate electrode GE1 as a mask. For example, boron (B) is implanted as the impurity element into the oxide semiconductor layer OS by ion implantation. In addition, instead of boron, another impurity element such as phosphorus (P) may be implanted into the oxide semiconductor layer OS.

In the ion implantation, the second conductive layer L2 and the fourth conductive layer L4, which have a relatively high density and a relatively large thickness, have a high property to block the implantation of the impurity element. Thus, the impurity element is hardly implanted into the region overlapping the second conductive layer L2 and the fourth conductive layer L4. On the other hand, the first conductive layer L1 and the third conductive layer L3 have a relatively low density and a small thickness. Thus, the impurity element easily passes through the portion of the first conductive layer L1 that does not overlap the second conductive layer L2 and the portion of the third conductive layer that does not overlap the fourth conductive layer L4. Therefore, the impurity element is implanted into the region that does not overlap the second conductive layer L2 and the fourth conductive layer L4. As a result, the impurity element is implanted into the region of the oxide semiconductor layer OS that does not overlap the second conductive layer L2 to form the impurity region OS_2 having a low resistance. Further, the impurity element is not implanted into the region of the oxide semiconductor layer OS that overlaps the second conductive layer L2 to form the channel region OS_1. Although the impurity element passes through the portion of the first conductive layer L1 that is exposed from the second conductive layer L2 as described above, the impurity element may be contained in the portion of the first conductive layer L1. Similarly, although the impurity element passes through the portion of the third conductive layer L3 that is exposed from the fourth conductive layer L4, the impurity element may be contained in the portion of the third conductive layer L3.

As described above, when the second transistor TR2 is an n-channel type transistor, the impurity element implanted into the silicon semiconductor layer SS is phosphorus. That is, the impurity element (phosphorus) contained in the silicon semiconductor layer SS is different from the impurity element (boron) implanted into the oxide semiconductor layer OS. In this case, it is necessary to protect the silicon semiconductor layer SS from the impurity element (boron) implanted into the oxide semiconductor layer OS. For this reason, the fourth conductive layer L4 is formed on the third conductive layer L3 in the second contact hole CH2 to prevent the impurity element (boron) implanted into the oxide semiconductor layer OS from being implanted into the silicon semiconductor layer SS.

Further, when the second transistor TR2 is a p-channel type transistor, the impurity element implanted into the silicon semiconductor layer SS is boron. When the impurity element implanted into the oxide semiconductor layer OS is phosphorus, the impurity element (boron) contained in the silicon semiconductor layer SS is different from the impurity element (phosphorus) implanted into the oxide semiconductor layer OS. In this case as well, the fourth conductive layer L4 is formed on the third conductive layer L3 in the second contact hole CH2 to prevent the impurity element (phosphorus) implanted into the oxide semiconductor layer OS from being implanted into the silicon semiconductor layer SS.

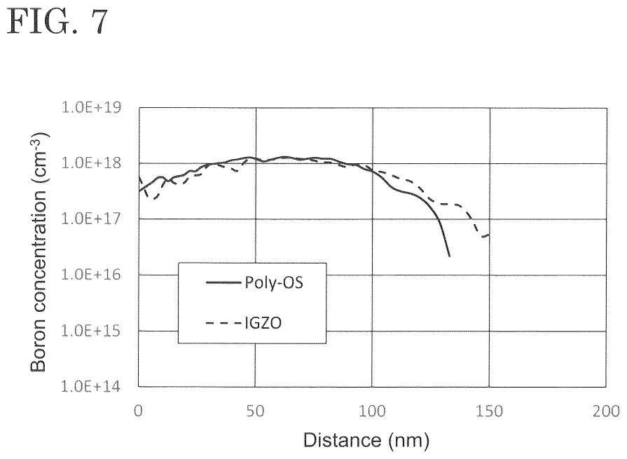

FIG. 7 shows a result of a simulation showing a concentration profile of boron implanted into the oxide semiconductor layer OS. The vertical and horizontal axes of the graph in FIG. 7 represent the distance from the surface and the boron concentration, respectively. Further, FIG. 7 shows not only the concentration profile of Poly-OS contained in the oxide semiconductor layer OS (a solid line in FIG. 7) but also a concentration profile of indium gallium zinc oxide (IGZO) as a conventional example (a dotted line in FIG. 7).

The simulation was performed using a “VICTORY PROCESS” manufactured by SILVACO Corporation under conditions of an acceleration voltage of 30 keV and a dose of 1×10¹³ cm⁻². As described above, Poly-OS contains a large amount of indium and has a high density. Therefore, in the simulation, the densities of Poly-OS and IGZO were calculated to be 7.179 g/cm3 and 6.1 g/cm³, respectively.

As shown in FIG. 7, the distance to which boron is implanted in Poly-OS is smaller than the distance to which boron is implanted in IGZO. That is, boron is not implanted in Poly-OS to a position far from the surface, compared with IGZO. This means that the implanted boron is likely to remain in Poly-OS. In other words, Poly-OS has a high blocking property for the implanted impurity element. Therefore, the impurity element does not pass through the oxide semiconductor layer OS including Poly-OS, and the oxide semiconductor layer OS can contain a larger amount of the impurity element. As a result, a larger number of oxygen deficiencies are generated in the impurity region OS_2, and the resistance of the impurity region OS_2 can be sufficiently reduced.

In the semiconductor device 1, since the impurity element is implanted into the oxide semiconductor layer OS through the first conductive layer L1 and the third conductive layer L3, the acceleration voltage in ion implantation may be increased. In this case, the blocking property for the impurity element is prominent. Specifically, even under conditions in which the impurity element passes through a conventional oxide semiconductor layer containing IGZO, the impurity element can be maintained in the oxide semiconductor layer OS containing Poly-OS. Therefore, in the semiconductor device 1, the resistance of the impurity region OS_2 overlapping the first conductive layer L1 and the third conductive layer L3 is sufficiently reduced.

As described above, in the semiconductor device 1, the connection wiring CN that directly and electrically connects the oxide semiconductor layer OS and the silicon semiconductor layer SS has a stacked structure including the thin third conductive layer L3 and the thick fourth conductive layer L4. However, the fourth conductive layer L4 is not formed so as to overlap the first contact hole CH1 through which the third conductive layer L3 is in contact with the oxide semiconductor layer OS.

Unlike the present embodiment, when an implantation of the impurity element is performed using ion implantation in the case where a thick connection wiring is formed so as to overlap the first contact hole CH1, the impurity is implanted only through the gap between the gate electrode and the connection wiring. In this case, an impurity region containing the impurity element does not overlap the first contact hole CH1. Therefore, since the electrical connection between the connection wiring and the oxide semiconductor layer does not become an ohmic contact, the second transistor TR2 does not have the desired performance. Further, since the electrical connection between the connection wiring and the oxide semiconductor layer is not stable, the reliability of the second transistor TR2 is deteriorated.

On the other hand, according to the present embodiment, the impurity element is implanted into the oxide semiconductor layer OS through the third conductive layer L3, so that the impurity region OS_2 can be formed by overlapping the first contact hole CH1. Therefore, since the electrical connection between the connection wiring CN and the oxide semiconductor layer OS becomes an ohmic contact, the second transistor TR2 has a desired performance. Further, since the electrical connection between the connection wiring CN and the oxide semiconductor layer OS is stable, the second transistor TR2 has high reliability.

Further, according to the present embodiment, the fourth conductive layer L4 is formed in the first contact hole CH1 in which the third conductive layer L3 and the silicon semiconductor layer SS are in contact with each other. Therefore, even when the impurity contained in the silicon semiconductor layer SS is different from the impurity implanted into the oxide semiconductor layer OS, the impurity element implanted into the oxide semiconductor layer OS can be prevented from being implanted into the silicon semiconductor layer SS. As a result, an increase in the contact resistance between the silicon semiconductor layer SS and the connection wiring CN is suppressed. Therefore, a decrease in the driving ability of the second transistor TR2 can also be suppressed. Further, since a separate process for suppressing the implantation of an undesired impurity element into the silicon semiconductor layer SS is not required, an increase in manufacturing costs is suppressed.

In addition, although the configuration in which the impurity region OS_2 of the oxide semiconductor layer OS is electrically connected to the silicon semiconductor layer SS is described in the present embodiment, a configuration in which the impurity region OS_2 of the oxide semiconductor layer OS is electrically connected to a metal layer such as a wiring is also possible.

### <Modification 1>

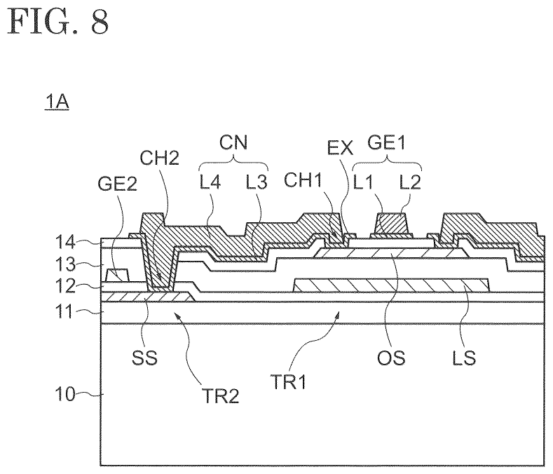

A modification of the present embodiment is described with reference to FIG. 8. In addition, the description of the similar configuration to the above-described configuration may be omitted in the following description.

FIG. 8 is a schematic cross-sectional view showing a configuration of a semiconductor device 1A according to a modification of an embodiment of the present invention.

The semiconductor device 1A shown in FIG. 8 is different from the semiconductor device 1 in the configuration of the fourth conductive layer L4. The third conductive layer L3 with which the fourth conductive layer L4 is in contact has the same configuration as that described above. That is, the third conductive layer L3 is in contact with the silicon semiconductor layer SS through the second contact hole CH2, and is in contact with the oxide semiconductor layer OS through the first contact hole CH1. Further, the third conductive layer L3 also includes an extension portion EX that extends from a position in the first contact hole CH1 in which the third conductive layer L3 is in contact with the oxide semiconductor layer OS toward the gate electrode GE1.

The fourth conductive layer L4 is formed between the first contact hole CH1 and the second contact hole CH2. The fourth conductive layer L4 is in contact with the third conductive layer L3 not only in the second contact hole CH2 but also in the first contact hole CH1. However, the fourth conductive layer L4 is not formed on the extension portion EX. That is, an edge surface of the fourth conductive layer L4 on the side of the first transistor TR1 overlaps the first contact hole CH1.

In the semiconductor device 1A, the implantation of the impurity element into a region of the oxide semiconductor layer OS that overlaps the first contact hole CH1 is suppressed. However, when a region of the third conductive layer L3 is made of a material that easily absorbs oxygen, the third conductive layer L3 is in contact with that region, so that oxygen in the region is absorbed to generate oxygen deficiencies. As a result, the source region or the drain region with a sufficiently low resistance is formed adjacent to the channel region OS_1.

Since the fourth conductive layer L4 is not formed in the extension portion EX in the semiconductor device 1A, the semiconductor device 1A can also achieve the same effects as those of the semiconductor device 1.

### <Modification 2>

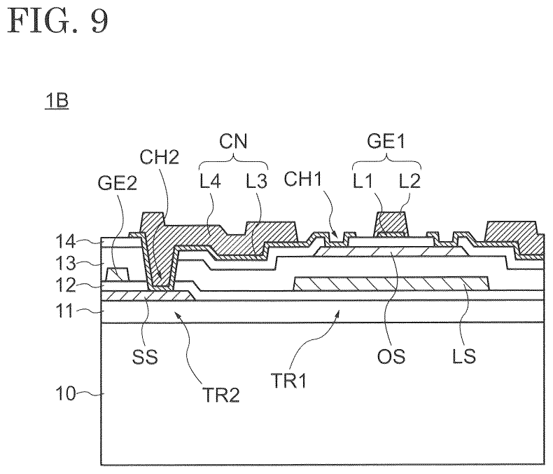

Another modification of the present embodiment is described with reference to FIG. 9. In addition, the description of the similar configuration to the above-described configuration may be omitted in the following description.

FIG. 9 is a schematic cross-sectional view showing a configuration of a semiconductor device 1B according to a modification of an embodiment of the present invention.

The semiconductor device 1B shown in FIG. 9 is different from the semiconductor device 1 in the configuration of the gate electrode GE1. In the gate electrode GE1 of the semiconductor device 1B, the second conductive layer L2 is formed so as to cover an upper surface and an edge surface of the first conductive layer L1. The width of the second conductive layer L2 is larger than the width of the first conductive layer L1 in the channel direction. Further, the second conductive layer L2 and the fourth conductive layer L4 are formed so as not to overlap the first contact hole CH1.

Also in the semiconductor device 1B, the impurity element can be implanted into the oxide semiconductor layer OS in a state in which the connection wiring CN is in contact with the oxide semiconductor layer OS through the first contact hole CH1. As a result, the impurity region OS_2 having a sufficiently low resistance can be formed so as to overlap the first contact hole CH1 and to be adjacent to the channel region OS_1. Therefore, the semiconductor device 1B can also achieve the same effects as those of the semiconductor device 1.

### <Modification 3>

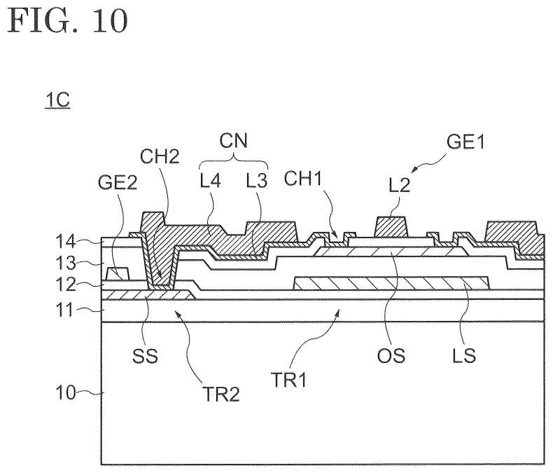

Another modification of the present embodiment is described with reference to FIG. 10. In addition, the description of the similar configuration to the above-described configuration may be omitted in the following description.

FIG. 10 is a schematic cross-sectional view showing a configuration of a semiconductor device 1C according to a modification of an embodiment of the present invention.

The semiconductor device 1C shown in FIG. 10 is different from the semiconductor device 1 in the configuration of the gate electrode GE1. In the gate electrode GE1 of the semiconductor device 1C, although the second conductive layer L2 is formed, the first conductive layer L1 is not formed. That is, the second conductive layer L2 is in contact with the insulating layer 14. Further, the second conductive layer L2 and the fourth conductive layer L4 are formed so as not to overlap with the first contact hole CH1.

Also in the semiconductor device 1C, the impurity element can be implanted into the oxide semiconductor layer OS in a state in which the connection wiring CN is in contact with the oxide semiconductor layer OS through the first contact hole CH1. As a result, the impurity region OS_2 having a sufficiently low resistance can be formed so as to overlap the first contact hole CH1 and to be adjacent to the channel region OS_1. Therefore, the semiconductor device 1C can also achieve the same effects as those of the semiconductor device 1.

### <Modification 4>

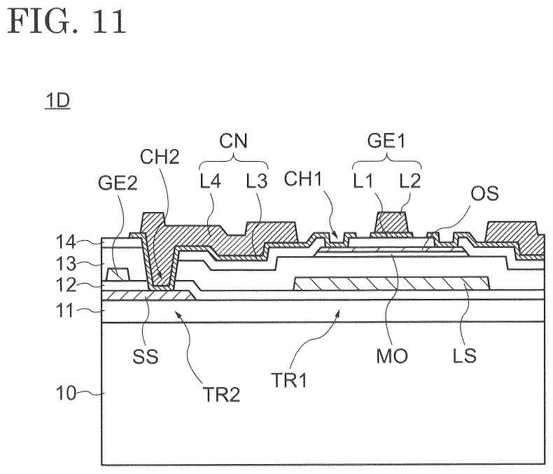

Another modification of the present embodiment is described with reference to FIG. 11. In addition, the description of the similar configuration to the above-described configuration may be omitted in the following description.

FIG. 11 is a schematic cross-sectional view showing a configuration of a semiconductor device 1D according to a modification of an embodiment of the present invention.

The semiconductor device 10 shown in FIG. 11 includes a metal oxide layer MO, which is different from the semiconductor device 1. That is, in the semiconductor device 1D, the metal oxide layer MO is provided under and in contact with the oxide semiconductor layer OS. An edge surface of the metal oxide layer MO is substantially aligned with the edge surface of the oxide semiconductor layer OS. The insulating layer 14 is provided on the insulating layer 13 so as to cover the edge surface of the metal oxide layer MO and the upper surface and the edge surface of the oxide semiconductor layer OS.

The metal oxide layer MO can function as a buffer layer that improves the crystallinity of the oxide semiconductor layer OS. In the first transistor TR1 including the oxide semiconductor layer OS with improved crystallinity, the field effect mobility is further improved.

A metal oxide containing aluminum as a main component is used for the metal oxide layer MO. The ratio of aluminum contained in the metal oxide layer MO may be greater than or equal to 5% and less than or equal to 70%, greater than or equal to 10% and less than or equal to 60%, or greater than or equal to 30% and less than or equal to 50% of the entire metal oxide layer MO. The above ratio may be a mass ratio or a weight ratio.

The thickness of the metal oxide layer MO is greater than or equal to 1 nm and less than or equal to 10 nm, preferably greater than or equal to 1 nm and less than or equal to 5 nm. It is preferable that aluminum oxide is used for the metal oxide layer MO. Aluminum oxide has high barrier properties against gases such as oxygen and hydrogen. Here, the barrier properties refer to a function of suppressing the permeation of gases such as oxygen and hydrogen.

In addition, a metal oxide containing a metal other than aluminum as a main component may be used for the metal oxide layer MO. For example, indium tin oxide (ITO), indium zinc oxide (IZO), indium gallium zinc oxide (IGZO), or the like can be used for the metal oxide layer MO.

The metal oxide layer MO can be deposited by a sputtering method or an atomic layer deposition method (ALD method). Further, the metal oxide layer MO can be patterned using the oxide semiconductor layer OS as a mask. As described above, the oxide semiconductor layer OS containing Poly-OS has excellent etching resistance. Therefore, even when the metal oxide layer MO is etched in the patterning of the metal oxide layer MO, the oxide semiconductor layer OS used as a mask is not etched. In the semiconductor device 1D, the oxide semiconductor layer OS can be used as a mask in the formation of the metal oxide layer MO, so that a photolithography process can be omitted.

Also in the semiconductor device 1D, the impurity element can be implanted into the oxide semiconductor layer OS in a state in which the connection wiring CN is in contact with the oxide semiconductor layer OS through the first contact hole CH1. As a result, the impurity region OS_2 having a sufficiently low resistance can be formed so as to overlap the first contact hole CH1 and to be adjacent to the channel region OS_1. Therefore, the semiconductor device 1D can also achieve the same effects as those of the semiconductor device 1. Further, since the Poy-OS is formed using the metal oxide layer MO as a buffer layer in the semiconductor device 1D, the crystallinity of the oxide semiconductor layer OS containing Poly-OS is improved. As a result, the first transistor TR1 has a higher field effect mobility.

### Second Embodiment

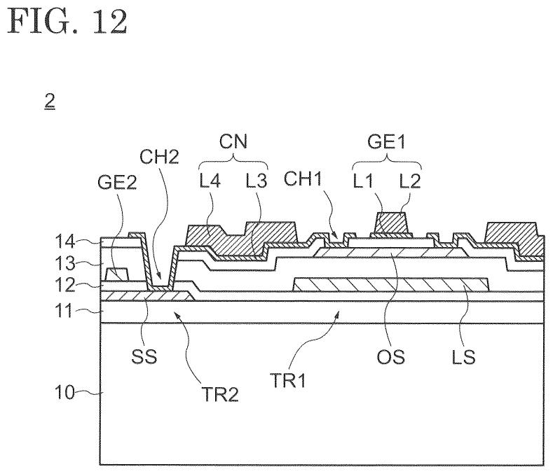

A semiconductor device 2 according to an embodiment of the present invention is described with reference to FIG. 12. In addition, the description of the similar configuration to that of the First Embodiment may be omitted in the following description.

FIG. 12 is a schematic cross-sectional view showing a configuration of a semiconductor device 2 according to an embodiment of the present invention.

The semiconductor device 2 shown in FIG. 12 is different from the semiconductor device 1 in the configuration of the connection wiring CN. In the connection wiring CN of the semiconductor device 2, the fourth conductive layer L4 is formed on the third conductive layer L3 between the first contact hole CH1 and the second contact hole CH2, and is not formed in the first contact hole CH1 and the second contact hole CH2. That is, the edge surface of the fourth conductive layer L4 does not overlap the first contact hole CH1 and the second contact hole CH2. In this case, when ion implantation is performed, the impurity element is implanted not only in the oxide semiconductor layer OS but also in the silicon semiconductor layer SS. However, in the semiconductor device 2, the impurity element contained in the silicon semiconductor layer SS is the same as the impurity element implanted in the oxide semiconductor layer OS. Specifically, the impurity element contained in the silicon semiconductor layer SS and the impurity element implanted in the oxide semiconductor layer OS are both phosphorus, or the impurity element contained in the silicon semiconductor layer SS and the impurity element implanted in the oxide semiconductor layer OS are both boron. Therefore, even when the impurity element is implanted into the oxide semiconductor layer OS after the impurity is implanted into the silicon semiconductor layer SS, the performance of the first transistor TR1 is not deteriorated.

In addition, the second conductive layer L2 and the fourth conductive layer L4 are formed so as not to overlap the first contact hole CH1.

Also in the semiconductor device 2, the impurity element can be implanted into the oxide semiconductor layer OS in a state in which the connection wiring CN is in contact with the oxide semiconductor layer OS through the first contact hole CH1. As a result, the impurity region OS_2 having a sufficiently low resistance can be formed so as to overlap the first contact hole CH1 and to be adjacent to the channel region OS_1. Therefore, the semiconductor device 2 can also achieve the same effects as those of the semiconductor device 1.

Each of the embodiments and modifications described above as the embodiments of the present invention can be appropriately combined and implemented as long as no contradiction is caused. Further, the addition, deletion, or design change of components, or the addition, deletion, or condition change of processes as appropriate by those skilled in the art based on each of the embodiments and modifications are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
an oxide semiconductor layer having a polycrystalline structure and comprising an impurity region containing an impurity element;
a gate electrode over the oxide semiconductor layer;
an insulating layer between the oxide semiconductor layer and the gate electrode;
a first contact hole penetrating the insulating layer and exposing the impurity region;
a second contact hole penetrating at least the insulating layer and having a greater depth than the first contact hole; and
a connection wiring electrically connecting the impurity region to a layer which is exposed in the second contact hole through the first contact hole and the second contact hole,
wherein the connection wiring comprises a first conductive layer and a second conductive layer on the first conductive layer, and
a portion of the first conductive layer that is exposed from the second conductive layer contains the impurity element.

2. The semiconductor device according to claim 1,
wherein the oxide semiconductor layer further comprises a channel region adjacent to the impurity region and having a higher electric resistivity,
the gate electrode comprises a third conductive layer formed in a same layer as the second conductive layer, and
a boundary between the channel region and the impurity region is substantially aligned with an edge portion of the third conductive layer.

3. The semiconductor device according to claim 2, wherein the gate electrode further comprises a fourth conductive layer formed in a same layer as the first conductive layer.

4. The semiconductor device according to claim 3, wherein the fourth conductive layer comprises a portion that is exposed from the third conductive layer.

5. The semiconductor device according to claim 3, wherein an edge surface of the fourth conductive layer is covered with the third conductive layer.

6. The semiconductor device according to claim 3, wherein a crystal structure of the impurity region is a same as a crystal structure of the channel region.

7. The semiconductor device according to claim 1, wherein the second conductive layer overlaps the first contact hole.

8. The semiconductor device according to claim 1, wherein the second conductive layer overlaps the second contact hole.

9. The semiconductor device according to claim 1, wherein the layer that is exposed through the second contact hole is a silicon semiconductor layer.

10. The semiconductor device according to claim 1, wherein the layer that is exposed through the second contact hole is a metal layer.

11. The semiconductor device according to claim 1, wherein an etching rate of the oxide semiconductor layer is less than 3 nm/min when the oxide semiconductor layer is etched using an etching solution containing phosphoric acid as a main component at 40° C.

12. The semiconductor device according to claim 11, wherein the etching solution contains nitric acid and acetic acid.

13. The semiconductor device according to claim 11,
wherein the oxide semiconductor layer is formed by performing a heat treatment on an oxide semiconductor film having an amorphous structure, and
an etching rate of the oxide semiconductor film is greater than or equal to 100 nm/min when the oxide semiconductor film is etched using the etching solution at 40° C.

14. The semiconductor device according to claim 1, wherein an etching rate of the oxide semiconductor layer is less than 5 nm/min when the oxide semiconductor layer is etched using 0.5% of a hydrofluoric acid solution at room temperature.

15. The semiconductor device according to claim 1,
wherein the oxide semiconductor layer comprises a plurality of metal elements,
the plurality of metal elements comprises indium, and
an atomic ratio of the indium to the plurality of metal elements is greater than or equal to 50%.

16. The semiconductor device according to claim 1, wherein a sheet resistance of the impurity region is less than or equal to 1000 Ω/sq.
